(19) United States
(12) Patent Application Publication
(10) Pub. No.: US 2019/0361407 A1
(43) Pub. Date: Nov. 28, 2019

(54) INSIGHTS FOR PHYSICAL SPACE USAGE

(71) Applicant: Microsoft Technology Licensing, LLC, Redmond, WA (US)

(72) Inventors: Matthew Evan VOGEL, Seattle, WA (US); Daniel ESCAPA, Seattle, WA (US); Hubert VAN HOOF, Redmond, WA (US); Gregory Christopher John VANDENBROUCK, Bellevue, WA (US); Alina Mihaela STANCIU, Redmond, WA (US); David John BRENNAN, Redmond, WA (US)

(73) Assignee: Microsoft Technology Licensing, LLC, Redmond, WA (US)

(21) Appl. No.: 15/989,047

(22) Filed: May 24, 2018

(51) Int. Cl. G05B 13/02; G01R 22/10

(52) U.S. Cl. CPC G05B 13/024; G01R 22/10

(57) ABSTRACT

A computing system includes a physical space monitoring interface configured to receive status parameters from a plurality of physical space monitors, each of the physical space monitors configured to report a status parameter for one more locations, devices, or people associated with a physical space. An efficiency analysis machine analyzes the status parameters to determine at least one usage efficiency metric for the physical space and at least one physical space efficiency insight. An analytics interface graphically displays the usage efficiency metric and the physical space efficiency insight, the physical space efficiency insight including a recommendation to change a physical space usage policy affecting one or more locations, devices, or people associated with the physical space to improve the usage efficiency metric.

### BACKGROUND

Interconnected “Internet of Things” (IoT) devices and sensors can be used to record and report data regarding their local environments. As modern workplaces come to embrace emerging technology, worker behaviors change, as do the relationships between physical spaces and the people and devices that occupy them.

### BRIEF DESCRIPTION OF THE DRAWINGS

FIG. 1 depicts an example location within a physical space including multiple devices and people.

FIG. 2 schematically shows an example computing system including a physical space monitoring machine, efficiency analysis machine, and analytics interface.

FIG. 3 schematically shows an example graph of locations, devices, and people associated with a physical space.

FIG. 4 depicts an example analytics interface.

FIG. 5 schematically shows an example computing system.

### DETAILED DESCRIPTION

Many buildings, structures, and other physical spaces include sensors useable to collect data regarding usage and performance of the physical space over time. However, such data frequently fails to capture the real-world context in which the physical space is used—e.g., the relationships between locations within the physical space and the people and devices that use those locations. Furthermore, existing monitoring solutions are cumbersome and lack usability.

Accordingly, the present disclosure is directed to an improved computing system for monitoring and improving usage efficiency of a physical space by changing policies affecting locations, devices, and people within the physical space. Specifically, a physical space monitoring machine receives status parameters from a plurality of physical space monitors, based on which an efficiency analysis machine determines usage efficiency metrics and efficiency insights for the physical space. Such insights can in some examples be based on external data sources—e.g., weather data, traffic data, or calendar information. For example, the efficiency analysis machine may report a total amount of electrical power consumed by devices in the physical space, and suggest ways in which this power consumption may be reduced. The usage efficiency metrics and physical space efficiency insights are presented in an analytics interface from which physical space performance can be reviewed and managed. Furthermore, the computing system can construct a “digital twin” of the physical space usable, for example, to simulate or predict how the space will be used under different conditions (e.g., with a new proposed floorplan or variable weather conditions).

Thus, the claimed computing system improves upon existing computational solutions for managing a physical space by presenting specific information in a manner that is faster and easier to review, and by offering specific recommendations to improve physical space performance in concrete ways. Furthermore, the claimed computing system improves efficiency of devices within the physical space, for example by reducing electrical power consumption of the physical space as a whole, meaning the devices collectively use less power while still performing their intended functions.

As indicated above, the present disclosure is generally directed to an improved computing system that improves the usage efficiency of a physical space. Improving “usage efficiency” can take a variety of suitable forms. For example, it can refer to improving infrastructure-related metrics such as total electrical power consumed, or more efficient heating. Improving usage efficiency of a physical space can also refer to improving employee health and happiness, repurposing underutilized portions of a building, cutting down on nonproductive meetings, etc. In general, any change that results in a measurable improvement to one or more devices, locations, or people associated with a physical space may be referred to as an improvement to the usage efficiency of the physical space.

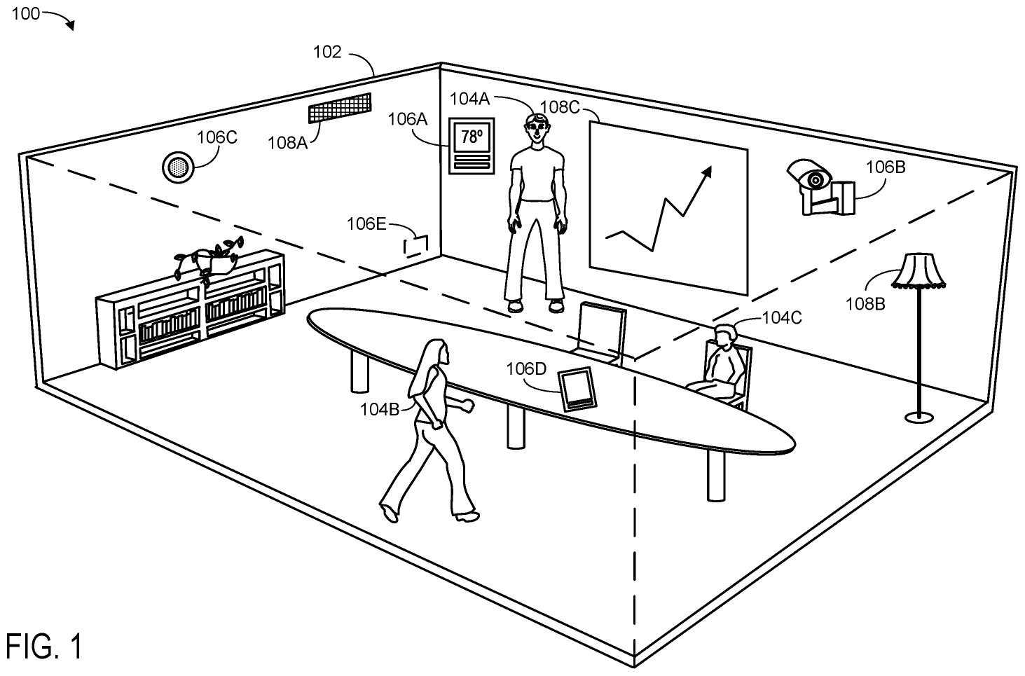

FIG. 1 illustrates an example location 102 within a physical space 100. Specifically, physical space 100 is an office building and location 102 is a meeting room within the building. It will be understood that physical space 100, as well as other “physical spaces” as the term is used in this disclosure, may take any suitable form and have any suitable number of internal areas, rooms, or other locations. For example, a “physical space” may be a building (e.g., residential or commercial), monument, landmark, utility, arena, warehouse, venue, etc. Similarly, physical spaces are described as including some number of “locations,” and these locations may take any suitable form. For example, a location may be a room, floor, or wing within a building, and need not correspond to physical walls or dividers within the physical space (e.g., an open space may be divided into a plurality of grid sections). In some examples, a physical space may include area outside of a structure or building (e.g., a park or campus grounds). Furthermore, a physical space need not include a structure at all, and may in some cases refer to an entirely outdoor area.

In FIG. 1, location 102 is occupied by several human users 104A-104C who work in physical space 100 and are attending a meeting within location 102. In other examples, a physical space may be occupied by residents, customers, visitors, tourists, etc. Location 102 also includes several electronic devices 106A-106E. Any or all of these devices may be described as physical space monitors, meaning they monitor conditions within the physical space, and report such conditions as status parameters to a physical space monitoring machine.

For example, physical space monitor 106A is a thermostat recording the current temperature in location 102. Air temperature has a bearing on human comfort level and can therefore negatively affect comfort and productivity of human users 104 within location 102. Physical space monitor 106A may additionally or alternatively measure air composition—relative levels of oxygen, carbon dioxide, carbon monoxide, humidity, ozone, etc.—which also relates to the comfort level of physical space 100. In some cases, physical space monitor 106A may coordinate with a heating, ventilation, and air conditioning (HVAC) system of the physical space, a portion of which is shown as ventilation fan 108A.

Physical space monitor 106B is a camera (e.g., visible light camera, infrared camera). Camera 106B may, for instance, record whether a location within the physical space is occupied, how many people are in the location, identities of any people within the location, a reason why the location is occupied (e.g., for a meeting), an illumination level of the location (e.g., via natural or artificial light), the on/off status of any devices within the physical space (e.g., whether a television is on), etc.

Physical space monitor 106C is a microphone that may, for instance, record a noise level within the location, detect human presence based on speech or other sounds consistent with human activity, detect speech patterns consistent with boredom, fatigue, etc.

Physical space monitor 106D is a personal electronic device that may include information regarding the current activity of a human user (e.g., attending a meeting, texting, checking email, browsing the Internet), include information regarding the user's schedule (e.g., how many meetings they have attended that day), etc. Physical space monitor 106D may, for example, take the form of a smartphone, tablet, laptop, and/or any other suitable electronic device. In some cases, data from physical space monitor 106D may be supplemented with data stored in a remote location, for example a cloud service (e.g., including stored files, HR records, communication records). Such a cloud service may additionally be referred to as a “physical space monitor,” as it stores and manages information relevant to current conditions within the physical space. In some examples, the current location of physical space monitor 106D may be tracked via WiFi connections, Bluetooth (or other wireless signal) beacons present in the physical space, etc. Presence of physical space monitor 106D in a specific area (e.g., meeting room) may be used to infer that the owner of the device is also present in the specific area.

Physical space monitor 106E is an electricity meter configured to measure electrical power consumption by devices within location 102. In some examples, physical space monitor 106E may be integrated into the electrical infrastructure of physical space 100, or physical space monitor 106E may be a separate sensor/meter installed by a user. Regardless, the electricity meter measures electrical power consumption of any or all devices within location 102 (i.e., devices 106A-106D, 108A, and 108B), and reports such information to a physical space monitoring machine of a computing system. In some examples, power consumption for each device may be reported separately (for example, when each device is on a separate circuit), and/or power consumption may be reported for the entire location as a whole.

Location 102 also includes a ventilation fan 108A and lamp 108B. These are examples of devices that may affect physical space 100 in measurable ways. For example, each of these devices, as well as other devices within physical space 100 (e.g., physical space monitors 106A-D) will consume electrical power. Similarly, devices 108A and 108B may affect conditions within the physical space in other quantifiable ways—for instance, by changing the temperature/air composition and illumination level respectively. In some examples, these devices may serve as physical space monitors in addition or as an alternative to the physical space monitors described above. For example, either or both of ventilation fan 108A and lamp 108B may include sensors configured to detect and report the current status of devices 108A and 108B to a physical space monitoring machine.

It will be understood that the various devices shown within physical space 100 are presented as nonlimiting examples. In general, a physical space may include any number of locations, devices, and people. Furthermore, any or all of the devices present within the physical space may be configured to serve as physical space monitors that report conditions within the physical space to a physical space monitoring machine.

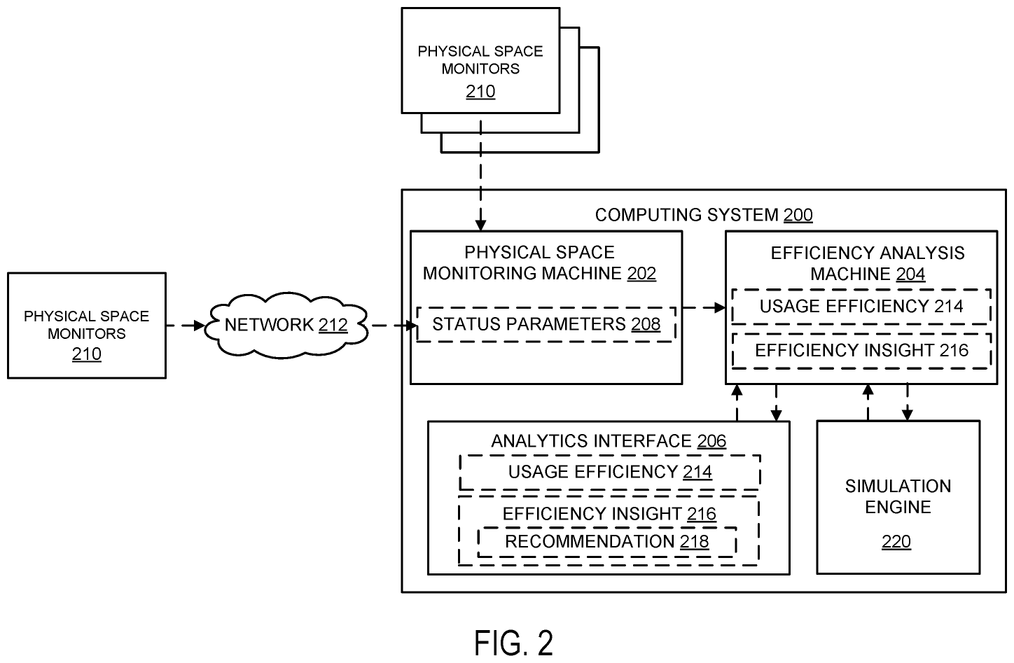

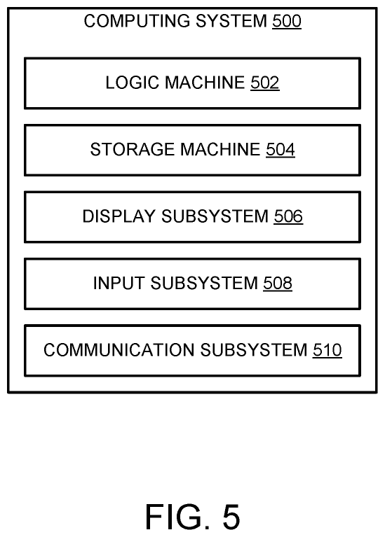

As indicated above, physical space monitors (such as those shown in FIG. 1) may report data or observations regarding locations, people, and devices associated with the physical space to a physical space monitoring machine of a computing system. An example computing system 200 is shown in FIG. 2. Computing system 200 may be implemented with any suitable computer hardware, and its functions may in some cases be distributed across any number of discrete devices. For example, the system may be implemented with a desktop computer, laptop computer, portable device (e.g., smartphone or tablet), wearable device (e.g. smartwatch or head-mounted display), media center, server computer, etc. In some examples, computing system 200 may be implemented via computing system 500 described below with respect to FIG. 5.

Computing system 200 includes a physical space monitoring machine 202 configured to receive status parameters from a plurality of physical space monitors. Computing system 200 also includes an efficiency analysis machine configured to determine usage efficiency metrics and efficiency insights based on the status parameters, and an analytics interface 206 configured to graphically display the efficiency metrics and insights. Furthermore, computing system 200 includes a prediction engine 220 configured to cooperate with efficiency analysis machine 204 in simulating and predicting how the physical space will be affected by hypothetical conditions. As discussed above, each of these components may be implemented on any suitable hardware and distributed across any suitable number of discrete devices. In some examples, any or all of the functions performed by the meeting evaluation machine, scheduler interface, and insight generation machine may be performed by computing system 500 of FIG. 5.

Physical space monitoring machine 202 is configured to receive and maintain a plurality of status parameters 208. A “status parameter” is any piece of information that indicates current conditions within or affecting a physical space. Non-limiting examples of such status parameters include air temperature, air composition, brightness, ambient noise level, room occupancy (e.g., expressed as a binary value or an actual number of individuals), device operation status, current device locations, identities of detected devices (expressed with any suitable granularity—e.g., human-readable identifiers, model numbers, general categories), electrical power consumption, employee records (e.g., job title, attendance, current location, workspace location, daily schedule, commute length, close associates, fatigue level, emotional state), building floorplan, tenant information (e.g., the identities of any entities using or leasing parts of a building), building schedules (e.g., opening/closing hours, times the building is normally occupied, times at which specific rooms are reserved—e.g., for meetings), etc. Furthermore, status parameters can include information not strictly related to conditions within the physical space, and yet have a bearing on how the physical space is used. For example, status parameters may include traffic data, weather data, calendar information, etc.

Status parameters 208 may be stored for any suitable length of time. In some examples, the status parameters may be intermittently archived or deleted—for example to save storage space. In other examples, however, physical space status parameters may be stored indefinitely. Over time, stored status parameters may be used to infer relationships and trends in building usage, which may be expressed as usage efficiency insights, as will be discussed in more detail below.

Furthermore, in some examples, status parameters 208 may be recorded and reported substantially all of the time, regardless of whether the physical space is currently open and/or occupied. In other examples, however, recording of physical space status parameters may be intermittently paused or terminated—for instance, during renovations of the physical space, special events, etc.

The physical space monitoring machine receives the status parameters from a plurality of physical space monitors 210, each being configured to report a status parameter for one or more locations, devices, or people associated with the physical space. In some cases, one or more physical space monitors may be accessed over a network 212, such as the Internet. Nonlimiting examples of physical space monitors include: temperature sensors, air composition sensors, motion sensors, brightness sensors, cameras (e.g., visible light or infrared), microphones, pressure sensors (e.g., embedded in a floor, table, or chairs), electricity meters, network communication interfaces (e.g., used to detect device presence via WiFi or Bluetooth), personal devices (e.g., usage history, current location), software applications running on local or remote devices, network information sources (e.g., weather databases, traffic reports, Internet search engines), etc. In some cases, status parameters may be manually defined.

The physical space monitoring machine may store or maintain the status parameters in any suitable way. In some cases, the status parameters may be useable to construct a “digital twin” or simulation of the physical space. For example, the status parameters may be used to construct a graph or chart that monitors conditions within the physical space in real time. Furthermore, a digital twin of a physical space may be used to make predictions as to how the physical space will be affected by hypothetical conditions. For example, based on trends learned over time, a digital twin may be used to predict how use of the physical space will change if more or fewer individuals work on a given floor, if the weather gets hotter or colder, if the building floorplan changes, etc.

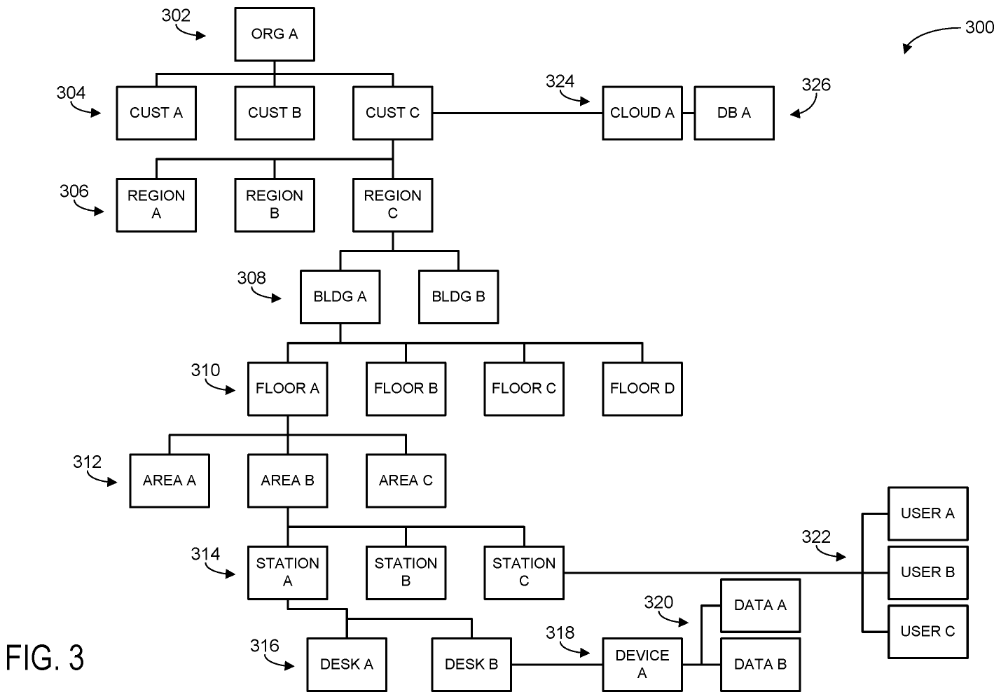

FIG. 3 shows an example of a graph 300 useable to monitor conditions and relationships within one or more physical spaces. It will be understood that a graph, such as graph 300, may be used in a variety of contexts, and need not be tied to any particular physical space or digital simulation of such a physical space. For example, graph 300 may be used by a single organization to track resources distributed between multiple physical spaces around the world or wherever they might be. As shown, graph 302 is divided into hierarchical levels, beginning with level 302. This level defines the organization (e.g., business) that created or maintains graph 300. Level 304 defines the organization's customer identities (e.g., any entities using products or services created by the organization, entities leasing or using physical spaces owned by the organization). Level 306 defines different regions that a particular customer (specifically customer C) does business in, while level 308 defines buildings (or other physical spaces) in use by the customer in region C. Level 310 specifies different floors (or other subdivisions) of building A. Floor A is further divided into multiple areas (e.g., rooms) in level 312.

The relationships described in the levels thus far may be relatively static, and often are not frequently updated or monitored. For example, the number of floors within a particular building, or the number of rooms on a particular floor, is not likely to suddenly change. Information in these levels may originate from any suitable source—e.g., one or more databases including customer records, sales records, property holdings, building floorplans, etc.

Levels 314 and beyond include information that may be less static in nature. For example, level 314 divides area B into three workstations, and workstation A includes two different desks, as shown in level 316. Workspace and desk arrangements may be substantially ad hoc and subject to change, for example as employees come and go, workspaces are rearranged, etc. Level 318 describes a device A that is associated with desk B, and level 320 includes two pieces of data or information reported by device A. Accordingly, device A may be a collection of sensors placed on or near desk B and configured to report information (e.g., status parameters) regarding the physical space and/or the device's current status. As examples, data A and data B may specify device-centric information (e.g., the current on/off status of device A, the current battery level of device A, the power consumption of device A), information regarding the physical space (e.g., air temperature or composition), user-centric information (e.g., the owner or user of device A), etc.

Level 322 includes information regarding the users associated with workstation C shown in level 314. Such information may include the identities of the users, the current whereabouts of the users, each user's daily schedule, and/or any of the other non-limiting examples of user-centric information provided above.

Level 324 specifies a cloud service associated with customer C, while level 326 includes a specific database of the cloud service. These may take any suitable forms. For example, as discussed above, a cloud service and/or database may be used to manage employee/HR records, communications, sales records, customer records, etc.

Taken together, the information included in graph 300 may be used to provide a comprehensive look at the status of one or more physical spaces (e.g., corresponding to a particular organization) at a particular point in time. It will be understood that the specific fields and relationships shown in graph 300 are nonlimiting. For example, an alternative version of graph 300 could be constructed that focuses on a particular physical space, for example one that includes multiple tenants or customers. Furthermore, the arrangements of the different levels may be changed in any suitable way—for example, devices, data, users, cloud services, databases, etc., may be associated with any level of the graph. Any of the levels shown in graph 300 may be omitted (e.g., the desk and workstation levels), and any additional levels may be added. A graph may in some examples include at least one field for each status parameter reported to the physical space monitoring machine.

In some examples, graph 300 may reflect the status of locations, devices, and people of one or more physical spaces at a current moment in time (e.g., a current moment). Accordingly, one or more fields of graph 300 may be updated with any suitable frequency. In other examples, however, each field of the graph may include one or more previous or superseded values. Furthermore, as will be discussed in more detail below, fields of graph 300 may be extrapolated forward in time to predict the status of a physical space in the future. This can be used to predict how the physical space will be affected under hypothetical conditions. For example, if the weather becomes hotter, air temperature within the physical space will change, as will illumination levels, worker sentiment, operation of the HVAC system (and therefore electrical power expenditure), etc. Any or all of these changes may be reflected in graph 300, and used to model how the physical space reacts to changing weather.

Returning to FIG. 2, computing system 200 includes an efficiency analysis machine 204 configured to analyze status parameters 208 to determine at least one usage efficiency metric 214 and at least one physical space efficiency insight 216. In general, a “usage efficiency metric” is an aggregation of one or more status parameters 208 that can be presented in an informative, human-readable form. A “physical space efficiency insight” includes a recommendation that is actionable to improve the usage efficiency of the physical space.

As a nonlimiting example, a usage efficiency metric might indicate an amount of electrical power used by all devices in a physical space. Such a metric may be calculated by tracking individual power consumption for each device and/or location within the physical space, and aggregating them to give an overall power consumption metric. Another usage efficiency metric may be an occupancy metric that describes a frequency of occupancy of one or more areas within the physical space. For example, in an office setting, an occupancy metric may include a list of rooms in the building (e.g., offices and conference rooms), and specify how frequently and for how long each room is occupied (expressed, for example as a percentage of a typical workday). This can be used, for example, to determine whether any rooms or areas in the physical space are over or underutilized. Another example usage efficiency metric may be a technician efficiency metric that indicates a time usage efficiency of one or more service technicians maintaining the physical space. For example, multiple different technicians (e.g., janitors, maintenance personnel), may be listed, along with a percentage indicating the portion of a typical workday they spend engaged in “productive work,” vs “nonproductive work” (e.g., servicing equipment that does not need service, restocking items that are sufficiently stocked, engaging in time-wasting recreational activities).

It will be understood that the above usage efficiency metrics are provided as nonlimiting examples. In general, an efficiency analysis machine may generate any number and variety of different usage efficiency metrics. Such metrics may be based on any status parameters, including any of the nonlimiting status parameters discussed above. In other words, usage efficiency metrics may be generated that describe average air temperature in the physical space, air quality, meeting length, employee emotional sentiment, etc. Furthermore, any or all of the efficiency metrics may be manually defined in addition to or as an alternative to being calculated or derived computationally.

In addition to usage efficiency metrics, efficiency analysis machine 204 is also configured to generate at least one physical space efficiency insight. A “physical space efficiency insight” includes a recommendation that is actionable to improve a usage efficiency of the physical space, specifically by changing a physical space usage policy affecting one or more locations, devices, or people associated with the physical space. For example, an efficiency insight focused on reducing electrical power consumption of a physical space may recommend altering behavior of a heating, ventilation, and air conditioning (HVAC) system of the physical space. HVAC systems are frequently inefficient and wasteful, in some cases even running both heating and air conditioning at the same time, and optimization of the HVAC system can result in substantial energy savings. In some cases, such optimization may be done on the basis of occupancy. This may include, for example, scaling back or ceasing any climate control operations in unoccupied rooms/spaces, altering HVAC operation based on current occupancy (e.g., turning on air conditioning for crowded rooms), etc.

Another example efficiency insight may include a recommendation to power off one or more identified devices that consume electrical power. Such devices can include, for example, computers, televisions, projectors, lights, etc., that are not typically needed when rooms are unoccupied (e.g., at night), and yet are inadvertently left on, and therefore unnecessarily consume electrical power. The efficiency analysis machine may identify one or more such devices (e.g., via monitoring of electrical power consumption in different areas of the physical space), and recommend that the devices be powered off at certain times of day, or generally when not being used. The devices may be identified in any suitable way—for example, by specifically providing a human-readable descriptor of the device, a model number, a specific location the device occupies within the physical space, a specific circuit or power outlet that the device draws power from, etc.

It will be understood that the efficiency analysis machine may generate any number and variety of different physical space efficiency insights, aimed at improving any usage efficiency metric. As additional nonlimiting examples, the efficiency analysis machine may generate an efficiency insight that recommends changing a floorplan of the physical space (e.g., to address space utilization concerns), moving designated workspaces for one or more identified people (e.g., to reduce a commute time, move people to be closer to their team or frequent collaborators, move people to more comfortable or productive environments), changing daily schedules of one or more service technicians (e.g., based on expertise or daily efficiency), etc.

The efficiency analysis machine may calculate the physical space efficiency insights in any suitable way. For example, the efficiency analysis machine may be configured to examine historical data (e.g., status parameters) for the physical space to identify relationships and trends. The efficiency analysis machine may therefore simulate changes to various conditions and relationships within the physical space, and predict how such changes would affect overall usage of the space. In some examples, such simulation and prediction may be done via a prediction engine 220 of computing system 200. In other words, the efficiency analysis machine cooperates with prediction engine 220 to simulate how a usage efficiency metric would be affected by a hypothetical change to the physical space usage policy, and determines the physical space efficiency insight based at least on results of the simulation. For example, the efficiency analysis machine may simulate the effects of reduced heating of the physical space, and conclude that electrical power would be conserved. However, the efficiency analysis machine may also infer that worker sentiment and productivity is negatively affected when the temperature of the physical space drops below a threshold. Accordingly, the efficiency analysis machine may output an efficiency insight including a recommendation to reduce heating of the physical space, but only when the physical space is unoccupied. Notably, the prediction engine may be used to simulate behavior of any physical space under any hypothetical conditions, and thus can be used to simulate performance of, for example, an updated floorplan for an existing physical space, or a new physical space altogether.

Computing system 200 also includes an analytics interface 206 configured to graphically display the usage efficiency metric 214 and the physical space efficiency insight 216. As discussed above, the physical space efficiency insight includes a recommendation 218 to change a usage policy affecting one or more locations, devices, or people to improve the usage efficiency metric (e.g., reduce power consumption in the physical space).

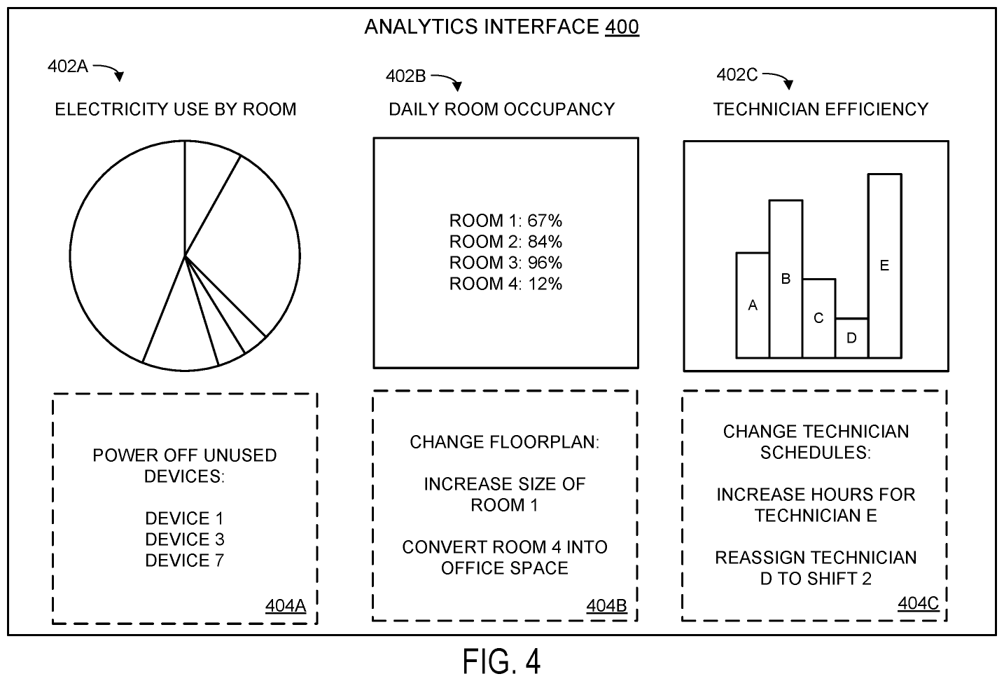

FIG. 4 shows an example analytics interface 400. Interface 400 is presented as a nonlimiting example. It will be understood that the specific layout and information shown in an analytics interface may vary from implementation to implementation. Furthermore, analytics interface 400 may be rendered and displayed by any suitable computer hardware. In some cases, analytics interface 400 may be rendered by computing system 500 described below with respect to FIG. 5.

As shown, interface 400 includes three usage efficiency metrics 402A-402C. Efficiency metric 402A is a pie chart that shows electrical power usage for various different rooms in the physical space. Efficiency metric 402A is paired with an efficiency insight 404A that includes a recommendation to power off several specific devices that are used infrequently, and yet continue to use electrical power. A different efficiency metric 402B lists several rooms within the physical space, and indicates how often during a typical day the rooms are occupied. This efficiency metric is also paired with an efficiency insight 402B, recommending that the floorplan of the physical space be changed to improve the occupancy metric. A third efficiency metric 402C is a bar graph, where each bar shows the daily efficiency of a service technician who helps to maintain the physical space. As discussed above, this reflects the amount of time the technician spends engaged in productive work, such as performing needed service on equipment, restocking, cleaning, etc., vs nonproductive work such as checking on fully-stocked or well-cleaned rooms. An efficiency insight 404C recommends changing the daily schedules of specific service technicians to improve their daily efficiency. This may include, for example, altering their daily route or hours, reassigning them to a different area or building, changing their duties based on expertise, etc.

The efficiency insights generated by an efficiency analysis machine may be implemented in any suitable way. In some examples, the efficiency analysis machine may be configured to implement the changed physical space usage policy recommended by the efficiency insight. For example, the efficiency analysis machine may send notifications or instructions to one or more human workers (e.g., managers, technicians) to update schedules, reconfigure devices, renovate locations, etc. Additionally, or alternatively, the efficiency analysis machine may be configured to implement one or more changes on its own, for example by directly modifying behavior of any devices in its network.

In some examples, the efficiency analysis machine may automatically implement the changes recommended in an efficiency insight once the insight is generated. In other examples, the efficiency insight may only be implemented in response to user input, for example provided to the analytics interface. The efficiency analysis machine may, for example, notify a user that changes will automatically be applied at a certain time unless the user specifically requests otherwise. Furthermore, the manner in which changes are implemented may vary from case to case—for example the efficiency analysis machine may implement minor changes automatically, though request user authorization for larger or more disruptive changes.

Though the above description primarily focused on the relationships between people, devices, and locations within existing physical spaces, as discussed above, the efficiency insight generation described above may additionally or alternatively be applied to simulated or hypothetical physical spaces. For example, based on trends and relationships observed in existing physical spaces (e.g., owned by a single customer, or in a database of all monitored physical spaces), the usage efficiency of a proposed floorplan can be evaluated. A customer planning to construct a new physical space, or modify an existing physical space, may upload a proposed floorplan to the efficiency analysis machine, along with indications of how the space will be used, which devices will be present, how many people will use the space, etc. The efficiency analysis machine (e.g., in cooperation with the prediction engine) may then generate efficiency insights in much the same manner as described above, for example predicting how much electrical power the space will consume and how this can be reduced, how crowded certain workspaces are likely to be and how this can be attenuated, etc. In some cases, the efficiency analysis machine may recommend modifications to the proposed floorplan to further improve the predicted efficiency of the proposed physical space.

In some embodiments, the methods and processes described herein may be tied to a computing system of one or more computing devices. In particular, such methods and processes may be implemented as a computer-application program or service, an application-programming interface (API), a library, and/or other computer-program product.

FIG. 5 schematically shows a non-limiting embodiment of a computing system 500 that can enact one or more of the methods and processes described above. Computing system 500 is shown in simplified form. Computing system 500 may take the form of one or more personal computers, server computers, tablet computers, home-entertainment computers, network computing devices, gaming devices, mobile computing devices, mobile communication devices (e.g., smart phone), and/or other computing devices.

Computing system 500 includes a logic machine 502 and a storage machine 504. Computing system 500 may optionally include a display subsystem 506, input subsystem 508, communication subsystem 510, and/or other components not shown in FIG. 5.

Logic machine 502 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 504 includes one or more physical devices configured to hold instructions executable by the logic machine to implement the methods and processes described herein. When such methods and processes are implemented, the state of storage machine 504 may be transformed—e.g., to hold different data.

Storage machine 504 may include removable and/or built-in devices. Storage machine 504 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 504 may include volatile, nonvolatile, dynamic, static, read/write, read-only, random-access, sequential-access, location-addressable, file-addressable, and/or content-addressable devices.

It will be appreciated that storage machine 504 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 502 and storage machine 504 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

The terms “module,” “program,” and “engine” may be used to describe an aspect of computing system 500 implemented to perform a particular function. In some cases, a module, program, or engine may be instantiated via logic machine 502 executing instructions held by storage machine 504. It will be understood that different modules, programs, and/or engines may be instantiated from the same application, service, code block, object, library, routine, API, function, etc. Likewise, the same module, program, and/or engine may be instantiated by different applications, services, code blocks, objects, routines, APIs, functions, etc. The terms “module,” “program,” and “engine” may encompass individual or groups of executable files, data files, libraries, drivers, scripts, database records, etc.

It will be appreciated that a “service”, as used herein, is an application program executable across multiple user sessions. A service may be available to one or more system components, programs, and/or other services. In some implementations, a service may run on one or more server-computing devices.

When included, display subsystem 506 may be used to present a visual representation of data held by storage machine 504. This visual representation may take the form of a graphical user interface (GUI). As the herein described methods and processes change the data held by the storage machine, and thus transform the state of the storage machine, the state of display subsystem 506 may likewise be transformed to visually represent changes in the underlying data. Display subsystem 506 may include one or more display devices utilizing virtually any type of technology. Such display devices may be combined with logic machine 502 and/or storage machine 504 in a shared enclosure, or such display devices may be peripheral display devices.

When included, input subsystem 508 may comprise or interface with one or more user-input devices such as a keyboard, mouse, touch screen, or game controller. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition; as well as electric-field sensing componentry for assessing brain activity.

When included, communication subsystem 510 may be configured to communicatively couple computing system 500 with one or more other computing devices. Communication subsystem 510 may include wired and/or wireless communication devices compatible with one or more different communication protocols. As non-limiting examples, the communication subsystem may be configured for communication via a wireless telephone network, or a wired or wireless local- or wide-area network. Specific examples of communication protocols include Bluetooth, Mesh networking, LoRa, BACNet, etc. Such protocols may be used to communicate with any number of other devices having any suitable locations and hardware configurations. In some embodiments, the communication subsystem may allow computing system 500 to send and/or receive messages to and/or from other devices via a network such as the Internet.

In an example, a computing system comprises: a physical space monitoring machine configured to receive status parameters from a plurality of physical space monitors, each of the physical space monitors configured to report a status parameter for one more locations, devices, or people associated with a physical space; an efficiency analysis machine configured to analyze the status parameters to determine at least one usage efficiency metric for the physical space and at least one physical space efficiency insight; and an analytics interface configured to graphically display the usage efficiency metric and the physical space efficiency insight, the physical space efficiency insight including a recommendation to change a physical space usage policy affecting one or more locations, devices, or people associated with the physical space to improve the usage efficiency metric. In this example or any other example, the efficiency analysis machine is useable to implement the recommendation to change the physical space usage policy in response to user input provided to the analytics machine. In this example or any other example, the efficiency analysis machine is further configured to automatically implement the recommendation to change the physical space usage policy. In this example or any other example, the usage efficiency metric indicates an amount of electrical power used by devices in the physical space. In this example or any other example, the recommendation to change the physical space usage policy includes altering behavior of a heating, ventilation, and air conditioning (HVAC) system of the physical space based on occupancy of the physical space. In this example or any other example, the recommendation to change the physical space usage policy includes disabling one or more identified devices that consume electrical power when not in use. In this example or any other example, the usage efficiency metric is an occupancy metric describing a frequency of occupancy of one or more areas within the physical space. In this example or any other example, the recommendation to change the physical space usage policy includes changing a floorplan of the physical space. In this example or any other example, the recommendation to change the physical space usage policy includes moving designated workspaces for one or more identified people. In this example or any other example, the usage efficiency metric is a technician efficiency metric indicating a time usage efficiency of one or more service technicians maintaining the physical space. In this example or any other example, the recommendation to change the physical space usage policy includes changing daily schedules of the one or more service technicians. In this example or any other example, the plurality of physical space monitors includes one or more software applications maintaining employee records and communications. In this example or any other example, the efficiency analysis machine is further configured to cooperate with a prediction engine of the computing system to simulate how the usage efficiency metric would be affected under a set of hypothetical conditions.

In an example, a method for physical space monitoring comprises: receiving status parameters from a plurality of physical space monitors, each of the physical space monitors configured to report a status parameter for one more locations, devices, or people associated with a physical space; analyzing the status parameters to determine at least one usage efficiency metric for the physical space and at least one physical space efficiency insight; and graphically displaying the usage efficiency metric and the physical space efficiency insight, the physical space efficiency insight including a recommendation to change a physical space usage policy affecting one or more locations, devices, or people associated with the physical space to improve the usage efficiency metric. In this example or any other example, the usage efficiency metric indicates an amount of electrical power used by devices in the physical space, and the recommendation to change the physical space usage policy includes altering behavior of a heating, ventilation, and air conditioning (HVAC) system of the physical space based on occupancy of the physical space. In this example or any other example, the usage efficiency metric indicates an amount of electrical power used by devices in the physical space, and the recommendation to change the physical space usage policy includes powering off one or more identified devices that consume electrical power when not in use. In this example or any other example, the usage efficiency metric is a technician efficiency metric indicating a time usage efficiency of one or more service technicians maintaining the physical space, and the recommendation to change the physical space usage policy includes changing daily schedules of the one or more service technicians.

In an example, a physical space analytics device comprises: a logic machine; and a storage machine holding instructions executable by the logic machine to: graphically display an analytics interface including a usage efficiency metric and a physical space efficiency insight, the physical space efficiency insight including a recommendation to change a physical space usage policy affecting one or more locations, devices, or people associated with a physical space to improve the usage efficiency metric; receive a user input to implement the recommendation to change the physical space usage policy; and automatically instruct one or more remote devices or people to alter their behavior in accordance with the changed physical space usage policy. In this example or any other example, the usage efficiency metric indicates an amount of electrical power used by devices in the physical space, and the recommendation to change the physical space usage policy includes altering behavior of a heating, ventilation, and air conditioning (HVAC) system of the physical space based on occupancy of the physical space. In this example or any other example, the usage efficiency metric indicates an amount of electrical power used by devices in the physical space, and the recommendation to change the physical space usage policy includes powering off one or more identified devices that consume electrical power when not in use.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A computing system, comprising:
a physical space monitoring machine configured to receive status parameters from a plurality of physical space monitors, each of the physical space monitors configured to report a status parameter for one more locations, devices, or people associated with a physical space;
an efficiency analysis machine configured to analyze the status parameters to determine at least one usage efficiency metric for the physical space and at least one physical space efficiency insight; and
an analytics interface configured to graphically display the usage efficiency metric and the physical space efficiency insight, the physical space efficiency insight including a recommendation to change a physical space usage policy affecting one or more locations, devices, or people associated with the physical space to improve the usage efficiency metric.

2. The computing system of claim 1, where the efficiency analysis machine is useable to implement the recommendation to change the physical space usage policy in response to user input provided to the analytics machine.

3. The computing system of claim 1, where the efficiency analysis machine is further configured to automatically implement the recommendation to change the physical space usage policy.

4. The computing system of claim 1, where the usage efficiency metric indicates an amount of electrical power used by devices in the physical sp ace.

5. The computing system of claim 4, where the recommendation to change the physical space usage policy includes altering behavior of a heating, ventilation, and air conditioning (HVAC) system of the physical space based on occupancy of the physical space.

6. The computing system of claim 4, where the recommendation to change the physical space usage policy includes disabling one or more identified devices that consume electrical power when not in use.

7. The computing system of claim 1, where the usage efficiency metric is an occupancy metric describing a frequency of occupancy of one or more areas within the physical space.

8. The computing system of claim 7, where the recommendation to change the physical space usage policy includes changing a floorplan of the physical space.

9. The computing system of claim 7, where the recommendation to change the physical space usage policy includes moving designated workspaces for one or more identified people.

10. The computing system of claim 1, where the usage efficiency metric is a technician efficiency metric indicating a time usage efficiency of one or more service technicians maintaining the physical space.

11. The computing system of claim 10, where the recommendation to change the physical space usage policy includes changing daily schedules of the one or more service technicians.

12. The computing system of claim 1, where the plurality of physical space monitors includes one or more software applications maintaining employee records and communications.

13. The computing system of claim 1, where the efficiency analysis machine is further configured to cooperate with a prediction engine of the computing system to simulate how the usage efficiency metric would be affected under a set of hypothetical conditions.

14. A method for physical space monitoring, comprising:
receiving status parameters from a plurality of physical space monitors, each of the physical space monitors configured to report a status parameter for one more locations, devices, or people associated with a physical space;
analyzing the status parameters to determine at least one usage efficiency metric for the physical space and at least one physical space efficiency insight; and
graphically displaying the usage efficiency metric and the physical space efficiency insight, the physical space efficiency insight including a recommendation to change a physical space usage policy affecting one or more locations, devices, or people associated with the physical space to improve the usage efficiency metric.

15. The computing system of claim 14, where the usage efficiency metric indicates an amount of electrical power used by devices in the physical space, and the recommendation to change the physical space usage policy includes altering behavior of a heating, ventilation, and air conditioning (HVAC) system of the physical space based on occupancy of the physical sp ace.

16. The computing system of claim 14, where the usage efficiency metric indicates an amount of electrical power used by devices in the physical space, and the recommendation to change the physical space usage policy includes powering off one or more identified devices that consume electrical power when not in use.

17. The computing system of claim 14, where the usage efficiency metric is a technician efficiency metric indicating a time usage efficiency of one or more service technicians maintaining the physical space, and the recommendation to change the physical space usage policy includes changing daily schedules of the one or more service technicians.

18. A physical space analytics device, comprising:
a logic machine; and
a storage machine holding instructions executable by the logic machine to:
graphically display an analytics interface including a usage efficiency metric and a physical space efficiency insight, the physical space efficiency insight including a recommendation to change a physical space usage policy affecting one or more locations, devices, or people associated with a physical space to improve the usage efficiency metric;
receive a user input to implement the recommendation to change the physical space usage policy; and
automatically instruct one or more remote devices or people to alter their behavior in accordance with the changed physical space usage policy.

19. The physical space analytics device of claim 18, where the usage efficiency metric indicates an amount of electrical power used by devices in the physical space, and the recommendation to change the physical space usage policy includes altering behavior of a heating, ventilation, and air conditioning (HVAC) system of the physical space based on occupancy of the physical space.

20. The physical space analytics device of claim 18, where the usage efficiency metric indicates an amount of electrical power used by devices in the physical space, and the recommendation to change the physical space usage policy includes powering off one or more identified devices that consume electrical power when not in use.
